(19) United States
(12) Patent Application Publication
(10) Pub. No.: US 2014/0264444 A1
(43) Pub. Date: Sep. 18, 2014

(54) STRESS-ENHANCING SELECTIVE EPITAXIAL DEPOSITION OF EMBEDDED SOURCE AND DRAIN REGIONS

(71) Applicant: INTERNATIONAL BUSINESS MACHINES CORPORATION, Armonk, NY (US)

(72) Inventors: Dechao Guo, Fishkill, NY (US); Yang Liu, Wappingers Falls, NY (US); Chengwen Pei, Danbury, CT (US); Yue Tan, Hopewell Junction, NY (US)

(73) Assignee: International Business Machines Corporation, Armonk, NY (US)

(21) Appl. No.: 13/798,467

(22) Filed: Mar. 13, 2013

(51) Int. Cl. H01L 29/66; H01L 29/78

(52) U.S. Cl. CPC H01L 29/66477; H01L 29/78
USPC 257/192; 257/368; 438/296

(57) ABSTRACT

Shallow trench isolation structures are formed within a semiconductor layer of a substrate to define an active area. The active area is recessed relative to a top surface of the shallow trench isolation structure. A shallow trench isolation (STI) spacer is formed on sidewalls of the shallow trench isolation structure around the periphery of the active area. After formation of a gate stack structure and a gate spacer, trenches are formed such that sidewalls of the trenches are vertically coincident with sidewalls of the gate spacer and the STI spacer. Epitaxial semiconductor material can be deposited into the trenches by selective epitaxy to form an embedded source region and an embedded drain region. Because all surfaces of the trenches are semiconductor surfaces, the entire trenches can be filled with the epitaxial semiconductor material, thereby enabling lateral confinement of stress within a channel region of a field effect transistor.

### BACKGROUND

The present disclosure relates to semiconductor devices, and particularly to a field effect transistor including an embedded source region and an embedded drain region that enhances transfer of stress to a channel region, and methods of manufacturing the same.

Formation of an embedded source region and an embedded drain region can be performed by recessing semiconductor material regions that are laterally bounded by shallow trench isolation structures and outer sidewalls of gate spacers. In this case, trenches recessed into the active region of the semiconductor material are formed such that dielectric surfaces of shallow trench isolation structures are physically exposed within the trenches. Selective epitaxy can be employed to grow a semiconductor material only from semiconductor surfaces while suppressing deposition of the semiconductor material on dielectric surfaces, thereby forming the embedded source region and the embedded drain region.

However, due to the tendency of the semiconductor material to form surfaces that do not contact dielectric materials, the embedded source region and the embedded drain region are formed with facets such that the surfaces of the embedded source region and the embedded drain region do not contact the dielectric surfaces of the shallow trench isolation structures. The embedded source region and the embedded drain region do not make physical contact with the surfaces of the shallow trench isolation structures. A predominant portion of the lateral stress generated by the lattice mismatch of the semiconductor material in the embedded source region and the embedded drain region and the underlying semiconductor material is dissipated by a volume change accompanying distortion of the faceted surfaces of the embedded source region and the embedded drain region. As a result, the lateral stress applied to the channel region of a field effect transistor is significantly reduced due to lack of physical contact between the embedded source/drain region and the shallow trench isolation structures.

### BRIEF SUMMARY

Shallow trench isolation structures are formed within a semiconductor layer of a substrate to define an active area. The active area is recessed relative to a top surface of the shallow trench isolation structure. A shallow trench isolation (STI) spacer is formed on sidewalls of the shallow trench isolation structure around the periphery of the active area. After formation of a gate stack structure and a gate spacer, trenches are formed such that sidewalls of the trenches are vertically coincident with sidewalls of the gate spacer and the STI spacer. Epitaxial semiconductor material can be deposited into the trenches by selective epitaxy to form an embedded source region and an embedded drain region. Because all surfaces of the trenches are semiconductor surfaces, the entire trenches can be filled with the epitaxial semiconductor material, thereby enabling lateral confinement of stress within a channel region of a field effect transistor.

According to an aspect of the present disclosure, a semiconductor structure includes a semiconductor material layer, which contains a first semiconductor material and embeds a shallow trench isolation structure that laterally surrounds an active region of the semiconductor material layer. A planar top surface of the active area is recessed below a top surface of the shallow trench isolation structure. The semiconductor structure further includes a shallow trench isolation spacer, which includes a dielectric material, overlies a periphery of the active region, and contacts sidewalls of the shallow trench isolation structure. A gate stack structure includes a vertical stack of a gate dielectric and a gate electrode, straddling the active region, contacts a top surface of the active region and overlies the shallow trench isolation spacer. An embedded semiconductor material region includes a second semiconductor material that is different from the first semiconductor material and embedded in the active region of the semiconductor material layer. An outer sidewall of the gate spacer is vertically coincident with an upper portion of an interface between the embedded semiconductor material region and a surface of the first semiconductor material.

According to another aspect of the present disclosure, a method of forming a semiconductor structure is provided. A shallow trench isolation structure is formed in a semiconductor material layer. The shallow trench isolation structure laterally surrounds an active region of the semiconductor material layer. A top surface of the active region is recessed relative to a top surface of the shallow trench isolation structure. A shallow trench isolation spacer is formed, which includes a dielectric material, overlies a periphery of the active region, and contacts sidewalls of the shallow trench isolation structure. A gate stack structure is formed, which includes a vertical stack of a gate dielectric and a gate electrode and straddles the active region. A gate spacer laterally surrounding the gate stack structure is formed. A trench is formed within the active region by etching a physically exposed portion of the active region. A sidewall of the trench is vertically coincident with an outer sidewall of the gate spacer. An embedded semiconductor material region within the active region is formed. The embedded semiconductor material region includes a second semiconductor material that is different from the first semiconductor material.

### BRIEF DESCRIPTION OF THE DRAWINGS

FIG. 1A is a top-down view of an exemplary semiconductor structure after formation of a shallow trench isolation structure and recessing of an active region according to an embodiment of the present disclosure.

FIG. 1B is a vertical cross-sectional view of the exemplary semiconductor structure along a vertical plane B-B′ of FIG. 1A.

FIG. 2A is a top-down view of the exemplary semiconductor structure after formation of a shallow trench isolation spacer according to an embodiment of the present disclosure.

FIG. 2B is a vertical cross-sectional view of the exemplary semiconductor structure along a vertical plane B-B′ of FIG. 2A.

FIG. 3A is a top-down view of the exemplary semiconductor structure after formation of a gate stack structure and a gate spacer according to an embodiment of the present disclosure.

FIG. 3B is a vertical cross-sectional view of the exemplary semiconductor structure along a vertical plane B-B′ of FIG. 3A.

FIG. 4A is a top-down view of the exemplary semiconductor structure after formation of a source-side trench and a drain-side trench according to an embodiment of the present disclosure.

FIG. 4B is a vertical cross-sectional view of the exemplary semiconductor structure along a vertical plane B-B′ of FIG. 4A.

FIG. 4C is a vertical cross-sectional view of the exemplary semiconductor structure along a vertical plane C-C′ of FIG. 4A.

FIG. 5A is a top-down view of the exemplary semiconductor structure after formation of an embedded source region and an embedded drain region within the source-side trench and the drain-side trench, respectively, according to an embodiment of the present disclosure.

FIG. 5B is a vertical cross-sectional view of the exemplary semiconductor structure along the plane B-B′ of FIG. 5A.

FIG. 6A is a vertical cross-sectional view of the exemplary semiconductor structure after formation of a contact-level dielectric layer, various contact via cavities, metal semiconductor alloy regions, and contact via structures according to an embodiment of the present disclosure.

FIG. 6B is a vertical cross-sectional view of the exemplary semiconductor structure along the plane B-B′ of FIG. 6A.

### DETAILED DESCRIPTION

As stated above, the present disclosure relates to a field effect transistor including an embedded source region and an embedded drain region that enhances transfer of stress to a channel region, and methods of manufacturing the same, which are now described in detail with accompanying figures. It is noted that like reference numerals refer to like elements across different embodiments. The drawings are not necessarily drawn to scale.

Referring to FIGS. 1A and 1B, an exemplary semiconductor structure according to an embodiment of the present disclosure includes a substrate 8, which includes a semiconductor material at least at a topmost portion thereof. The substrate 8 can be provided as a bulk semiconductor substrate, a semiconductor-on-insulator (SOI) substrate, or a hybrid substrate including a bulk semiconductor portion and an SOI portion.

A top portion of the substrate 8 includes a semiconductor material layer 10, which includes a first semiconductor material. The first semiconductor material can be, for example, single crystalline silicon, single crystalline germanium, a single crystalline alloy of at least two of silicon, germanium, and carbon, a single crystalline compound semiconductor material, a polycrystalline elemental semiconductor material, a polycrystalline alloy of at least two of silicon, germanium, and carbon, a polycrystalline compound semiconductor material, or an amorphous semiconductor material. In one embodiment, the first semiconductor material is single crystalline.

A shallow trench isolation structure 20 is formed in an upper portion of the semiconductor material layer 10, for example, by formation of a shallow trench that laterally surrounds a region of the semiconductor material layer 10, which is herein referred to as an “active region” in which a semiconductor device such as a field effect transistor can be formed. The shallow trench is filled with a dielectric material such as silicon oxide, silicon nitride, and/or silicon oxynitride to form the shallow trench isolation structure 20. The active region is a portion of the semiconductor material layer 10 that is laterally surrounded by the shallow trench isolation structure 20. In one embodiment, the area of the active region can be rectangular.

The shallow trench isolation structure is formed such that a planar top surface of the semiconductor material layer 10 is recessed below a top surface of the shallow trench isolation structure 20. In one embodiment, the shallow trench isolation structure 10 can be formed by depositing at least one pad layer (not shown) over the semiconductor material layer 10 such that the top surface of the shallow trench isolation structure 20 is above the interface between the semiconductor material layer 10, and by subsequently removing the at least one pad layer selective to the shallow trench isolation structure 20. The at least one pad layer may include a dielectric material different from the dielectric material of the shallow trench isolation structure. Alternately or additionally, the top surface of the semiconductor material layer 10 may be recessed relative to the top surface of the shallow trench isolation structure 20 by an etch that is selective to the shallow trench isolation structure 20. The etch can be an isotropic etch such as a wet etch, or can be an anisotropic etch such as a reactive ion etch. The recess depth rd, which is the vertical distance between the top surface of the semiconductor material layer 10 and a horizontal plane including the top surface of the shallow trench isolation structure 20, can be from 3 nm to 100 nm, although lesser and greater thicknesses can also be employed.

Referring to FIGS. 2A and 2B, a shallow trench isolation spacer 22 is formed on a peripheral portion of the active region. The shallow trench isolation spacer 22 can be formed, for example, by depositing a conformal dielectric material layer and anisotropically etching the conformal dielectric material layer to remove horizontal portions of the conformal dielectric material layer. The conformal dielectric material layer can include a dielectric material such as silicon oxide, silicon nitride, silicon oxynitride, a dielectric metal oxide having a dielectric constant greater than 8.0, or a combination thereof. The conformal dielectric material layer can be deposited, for example, by chemical vapor deposition (CVD) and/or atomic layer deposition (ALD). The thickness of the conformal dielectric material layer can be, for example, from 2 nm to 50 nm, although lesser and greater thicknesses can also be employed.

The anisotropic etch of the conformal dielectric material layer can be performed, for example, by a reactive ion etch. In one embodiment, the reactive ion etch can be selective to the semiconductor material of the semiconductor material layer 10. A remaining vertical portion of the conformal dielectric material layer after the anisotropic etch constitutes the shallow trench isolation spacer 22. The shallow trench isolation spacer 22 overlies a periphery of the active region, and contacting sidewalls of the shallow trench isolation structure 20. The shallow trench isolation spacer 22 is a single contiguous dielectric material structure. In one embodiment, the shallow trench isolation spacer 22 can be a ring-shaped structure, i.e., can have a single hole therein. As used herein, a structure is “ring-shaped” if the structure is “topologically homeomorphic” to a torus, i.e., can be continuously stretched without creating or destroying a hole into a torus. In one embodiment, the shallow trench isolation spacer 22 can have the same base width throughout the entirety thereof. As used herein, a “base width” refers to the width of a base, i.e., a bottommost surface.

Referring to FIGS. 3A and 3B, a gate stack structure (50, 52, 58) can be formed over the active region, the shallow trench isolation spacer 22, and the shallow trench isolation structure 20. The gate stack structure (50, 52, 58) straddles the active region, and includes a vertical stack of a gate dielectric 50, a gate electrode 52 overlying the gate dielectric 50, and a gate cap dielectric 58 overlying the gate electrode 52. The gate stack structure (50, 52, 58) includes a gate electrode for the transistor to be formed on the active region, which functions as an active gate stack structure. The gate stack structure (50, 52, 58) includes a pair of lengthwise sidewalls that extends along the lengthwise direction of the gate stack structure (50, 52, 58) and straddling the active region. As used herein, a “lengthwise direction” of a structure refers to a horizontal direction along which the lateral extent of the structure is the greatest. As used herein, a “widthwise direction” of a structure refers to a horizontal direction that is perpendicular to the lengthwise direction of the structure. Each lengthwise sidewall of the gate stack structure (50, 52, 58) can be substantially vertical, and can include a sidewall of the gate dielectric 50, a sidewall of the gate electrode 52, and a sidewall of the gate cap dielectric 58. As used herein, a surface is “substantially vertical” if the deviation of the surface from a vertical plane predominantly (i.e., more than 50%) due to atomic level roughness of the surface. The gate stack structure (50, 52, 58) contacts a top surface of the active region, two surface portions of the shallow trench isolation structure 22, and a top surface of the shallow trench isolation structure 20. Specifically, the bottom surface of the gate dielectric 50 contacts the top surface of the active region, the two surface portions of the shallow trench isolation structure 22, and the top surface of the shallow trench isolation structure 20.

The gate stack structure (50, 52, 58) can be formed, for example, by formation of a stack of a gate dielectric layer including a dielectric material, a gate electrode layer including at least one conductive material, and a gate cap dielectric layer including a dielectric material, and by subsequent patterning of the stack of the gate dielectric layer, the gate electrode layer, and the gate cap dielectric layer by a combination of lithographic methods that form a patterned photoresist layer and at least one anisotropic etch that etches physically exposed portions of the stack employing the patterned photoresist layer as an etch mask.

An interface between the gate dielectric 50 and the first semiconductor material of the active region is located below a horizontal plane including an interface between the gate dielectric 50 and the shallow trench isolation structure 20. The gate stack structure (50, 52, 58) is formed on a surface of the shallow trench isolation spacer 22.

A gate spacer 62 can be formed on the sidewalls of the gate stack structures (50, 52, 58). Specifically, the gate spacer 62 can be formed by a conformal deposition of a dielectric material layer and a subsequent anisotropic etch (such as a reactive ion etch) that removes horizontal portions of the deposited dielectric material layer. The remaining vertical portions of the dielectric material layer constitute the gate spacer 62 which laterally surround each of the gate stack structure (50, 52, 58). The gate spacer 62 includes a dielectric material such as silicon oxide, silicon nitride, silicon oxynitride, or a combination thereof. The thickness of the gate spacers 62 can be in a range from 5 nm to 100 nm, although lesser and greater thicknesses can also be employed.

Referring to FIGS. 4A, 4B, and 4C, an anisotropic etch is performed employing an etch chemistry that etches the first semiconductor material selective to the dielectric materials of the gate cap dielectric 58 and the gate spacer 62, i.e., without etching the dielectric materials of the gate cap dielectric 58 and the gate spacers 62. Physically exposed regions of the active region are etched by the anisotropic etch. As the physically exposed surfaces of the active region are vertically recessed by the anisotropic etch, trenches are formed in the portions of the active region that are not covered by the gate stack structure (50, 52, 58) or by the gate spacer 62. The anisotropic etch removes the first semiconductor material from below the horizontal plane including the interface between the gate dielectric 50 and the active region.

In one embodiment, two trenches can be formed in the active region such that a first trench 31 is formed on one side of the combination of the gate stack structure (50, 52, 58) and the gate spacer 62, and a second trench 39 is formed on the opposite side of the combination of the gate stack structure (50, 52, 58) and the gate spacer 62. A source region can be subsequently formed within the first trench 31, and therefore, the first trench 31 is herein referred to as a source-side trench. A drain region can be subsequently formed within the second trench 39, and therefore, the second trench 39 is herein referred to as a drain-side trench.

Vertical surfaces of the shallow trench isolation structure that are along the widthwise direction of the gate stack structure (50, 52, 58) can be physically exposed in each of the first and second trenches (31, 39). All sidewalls of the first and second trenches (31, 39) can be substantially vertical.

In one embodiment, an outer sidewall of the gate spacer 62 can be vertically coincident with a sidewall of the first trench 31, and another outer sidewall of the gate spacer 62 can be vertically coincident with a sidewall of the second trench 39. As used herein, a first surface is vertically coincident with a second surface if there exists a vertical plane from which the first surface and the second surface do not deviate by more than the sum of the atomic level roughness of the first surface and the atomic level roughness of the second surface.

Referring to FIGS. 5A and 5B, an embedded semiconductor material region can be formed within each of the first and second trenches (31, 39) within the active region. Specifically, a second semiconductor material that is different from the first semiconductor material can be deposited within each of the first and second trenches (31, 39) to form the embedded semiconductor material region. The deposition of the second semiconductor material can be performed, for example, by selective epitaxy, in which a reactant including the second semiconductor material and an etchant gas (such as helium) and an optional carrier gas (such as hydrogen) is concurrently or alternately flowed into a process chamber containing the exemplary semiconductor structure. During the selective epitaxy process, the second semiconductor material grows on semiconductor surfaces and does not grow on dielectric surfaces. The embedded semiconductor material region formed within the first trench 31 is herein referred to as an embedded source region 72, and the embedded semiconductor material region formed within the second trench 39 is herein referred to as an embedded drain region 78.

The second semiconductor material in the embedded semiconductor material regions (72, 78) can be doped with electrical dopants, which can be p-type dopants or n-type dopants. If the first semiconductor material has a doping of the first conductivity type, the second semiconductor material can have a doping of the second conductivity type, which is the opposite of the first conductivity type. For example, if the first conductivity type is p-type, the second conductivity type is n-type, and vice versa. The doping of the second semiconductor material can be performed, for example, by in-situ doping during the selective epitaxy process.

If the first semiconductor material is single crystalline, the second semiconductor material can be single crystalline and can be epitaxially aligned to the first semiconductor material. In one embodiment, the first semiconductor material can be single crystalline silicon or a single crystalline silicon-germanium alloy, and the second semiconductor material can be a boron-doped single crystalline silicon germanium alloy or an n-doped and carbon-doped single crystalline silicon.

Within the exemplary semiconductor structure illustrated in FIGS. 5A and 5B, the semiconductor material layer 10 includes the first semiconductor material and embeds the shallow trench isolation structure 20 that laterally surrounds the active region of the semiconductor material layer 10. The gate stack structure (50, 52, 58) includes the vertical stack of the gate dielectric 50 and the gate electrode 52, straddles the active region, and contacts the top surface of the active region. Each embedded semiconductor material region (72, 78) includes the second semiconductor material, and is embedded in the active region of the semiconductor material layer 10.

The embedded source region 72 is embedded within the active region, and is laterally spaced from the embedded drain region 78. An outer sidewall of the gate spacer 62, which is a dielectric material structure, is vertically coincident with an upper portion of an interface between the embedded source region 72 and a surface of the first semiconductor material of the active region, which is a surface of a body region of the field effect transistor. The embedded drain region 78 is embedded within the active region, and is laterally spaced from the embedded source region 72. Another outer sidewall of the gate spacer 62 is vertically coincident with an upper portion of an interface between the embedded drain region 78 and another surface of the first semiconductor material of the active region, which is another surface of a body region of the field effect transistor. The gate dielectric 50 is a gate dielectric of the field effect transistor, and the gate electrode 52 is a gate electrode of the field effect transistor.

In one embodiment, the sidewalls of the embedded semiconductor material regions (72, 78) can be faceted so that the dielectric surfaces of the shallow trench isolation structure 20 do not contact any surface of the embedded semiconductor material region (72, 78). In one embodiment, a portion of each embedded semiconductor material region (72, 78) can protrude above a horizontal plane including the top surface of the active region, i.e., the horizontal plane including the bottom surface of the gate dielectric 50, and can include at least one faceted crystallographic surface.

In one embodiment, peripheries of faceted crystallographic surfaces may be coincident with a boundary between a dielectric material and the second semiconductor material. For example, peripheries of faceted crystallographic surfaces of the embedded semiconductor material regions (72, 78) can coincide with the edges at which outer sidewalls of the gate spacer 62 adjoins the active region.

Referring to FIGS. 6A and 6B, a contact-level dielectric layer 90 can be deposited and planarized, for example, by chemical mechanical planarization. The contact-level dielectric layer 90 includes a dielectric material such as silicon oxide, silicon nitride, silicon oxynitride, and/or porous or non-porous organosilicate glass (OSG). Various contact via holes are formed within the contact-level dielectric layer 90, and are subsequently filled with at least one conductive material to form various contact via structures. The contact via structures can include, for example, a source-side contact via structure 92, a drain-side contact via structure 98, and a gate-side contact via structure 95. Optionally, various metal semiconductor alloy regions can be formed, which can include, for example, a source-side metal semiconductor alloy region 82, a drain-side metal semiconductor alloy region 88, and a gate-side metal semiconductor alloy region 95.

In one embodiment, the contact-level dielectric layer 90 can extend below the horizontal plane of the interface between the gate dielectric 50 and the semiconductor material layer 10, and can overlie a portion of each embedded semiconductor material region (72, 78). In one embodiment, the contact-level dielectric layer 90 can physically contact a surface of each embedded semiconductor material region (72, 78) that is not subjected to metal semiconductor alloy formation.

The various exemplary semiconductor structure of the present disclosure provide a physical and areal contact for all sidewalls of the embedded semiconductor material regions (72, 78) with a sidewall of the active region of the semiconductor material layer 10 by laterally offsetting the embedded semiconductor material regions (72, 78) from the shallow trench isolation structure with the shallow trench isolation spacer 22. Thus, the stress generated by the lattice mismatch of the first and second semiconductor materials is not dissipated by volume change in the cavities, but is effectively contained by the shallow trench isolation structure 20 and the peripheral portions of the active region, and is transmitted to the channel region of the field effect transistor between the embedded semiconductor material regions (72, 78), thereby enhancing the on-current of the field effect transistor.

While the present disclosure has been particularly shown and described with respect to preferred embodiments thereof, it will be understood by those skilled in the art that the foregoing and other changes in forms and details may be made without departing from the spirit and scope of the present disclosure. Each of the various embodiments of the present disclosure can be implemented alone, or in combination with any other embodiments of the present disclosure unless expressly disclosed otherwise or otherwise impossible as would be known to one of ordinary skill in the art. It is therefore intended that the present disclosure not be limited to the exact forms and details described and illustrated, but fall within the scope of the appended claims.

What is claimed is:

1. A semiconductor structure comprising:
a semiconductor material layer including a first semiconductor material and embedding a shallow trench isolation structure that laterally surrounds an active region of said semiconductor material layer, wherein a planar top surface of said active area is recessed below a top surface of said shallow trench isolation structure;
a shallow trench isolation spacer comprising a dielectric material, overlying a periphery of said active region, and contacting sidewalls of said shallow trench isolation structure;
a gate stack structure including a vertical stack of a gate dielectric and a gate electrode, straddling said active region, contacting a top surface of said active region and overlying said shallow trench isolation spacer; and
an embedded semiconductor material region including a second semiconductor material that is different from said first semiconductor material and embedded in said active region of said semiconductor material layer.

2. The semiconductor structure of claim 1, wherein an interface between said gate dielectric and said first semiconductor material is located below a horizontal plane including an interface between said gate dielectric and said shallow trench isolation structure.

3. The semiconductor structure of claim 1, wherein said gate dielectric contacts two surface portions of said shallow trench isolation spacer.

4. The semiconductor structure of claim 1, wherein said shallow trench isolation spacer is a ring-shaped structure.

5. The semiconductor structure of claim 1, wherein said shallow trench isolation spacer has a same base width throughout.

6. The semiconductor structure of claim 1, wherein all surfaces of said embedded semiconductor material region below a horizontal plane including said top surface of said active region are in physical contact with surfaces of said first semiconductor material.

7. The semiconductor structure of claim 1, wherein said first semiconductor material is single crystalline, and said second semiconductor material is single crystalline and epitaxially aligned to said first semiconductor material.

8. The semiconductor structure of claim 7, wherein said first semiconductor material is single crystalline silicon or a single crystalline silicon-germanium alloy, and said second semiconductor material is a boron-doped single crystalline silicon germanium alloy or an n-doped and carbon-doped single crystalline silicon.

9. The semiconductor structure of claim 1, wherein a portion of said embedded semiconductor material region protrudes above a horizontal plane including said top surface of said active region and includes at least one faceted crystallographic surface.

10. The semiconductor structure of claim 1, wherein an outer sidewall of said gate spacer is vertically coincident with an upper portion of an interface between said embedded semiconductor material region and a surface of said first semiconductor material.

11. The semiconductor structure of claim 10, further comprising another embedded semiconductor material region that is embedded within said active region and laterally spaced from said embedded semiconductor material region, wherein another outer sidewall of said dielectric material structure is vertically coincident with an upper portion of an interface between said another embedded semiconductor material region and yet another surface of said first semiconductor material.

12. The semiconductor structure of claim 11, wherein one of said embedded semiconductor material region and said another embedded semiconductor material region is an embedded source region of a field effect transistor, and another of said embedded semiconductor material region and said another embedded semiconductor material region is an embedded drain region of said field effect transistor, and said active region includes a body region of said field effect transistor.

13. A method of forming a semiconductor structure comprising:
forming a shallow trench isolation structure in a semiconductor material layer, said shallow trench isolation structure laterally surrounding an active region of said semiconductor material layer, and a top surface of said active region is recessed relative to a top surface of said shallow trench isolation structure;
forming a shallow trench isolation spacer comprising a dielectric material, overlying a periphery of said active region, and contacting sidewalls of said shallow trench isolation structure;
forming a gate stack structure comprising a vertical stack of a gate dielectric and a gate electrode and straddling said active region;
forming a gate spacer laterally surrounding said gate stack structure;
forming a trench within said active region by etching a physically exposed portion of said active region, wherein a sidewall of said trench is vertically coincident with an outer sidewall of said gate spacer; and
forming an embedded semiconductor material region within said active region, said embedded semiconductor material region including a second semiconductor material that is different from said first semiconductor material.

14. The method of claim 13, wherein said gate stack structure is formed on a surface of said shallow trench isolation spacer.

15. The method of claim 13, wherein an interface between said gate dielectric and said first semiconductor material is formed below a horizontal plane including an interface between said gate dielectric and said shallow trench isolation structure.

16. The method of claim 1, wherein said shallow trench isolation spacer is formed as a ring-shaped structure.

17. The method of claim 13, wherein an outer sidewall of said gate spacer is vertically coincident with an upper portion of an interface between said embedded semiconductor material region and a surface of said first semiconductor material.

18. The method of claim 13, wherein all surfaces of said trench below a horizontal plane including said top surface of said active region are semiconductor surfaces.

19. The method of claim 13, wherein said forming of said embedded semiconductor material region comprises depositing said second semiconductor material by selective epitaxy in which said second semiconductor material grows on semiconductor surfaces and does not grow on dielectric surfaces.

20. The method of claim 19, wherein said first semiconductor material is single crystalline silicon or a single crystalline silicon-germanium alloy, and said second semiconductor material is a boron-doped single crystalline silicon germanium alloy or an n-doped and carbon-doped single crystalline silicon.
